(19) United States
(12) Patent Application Publication
(10) Pub. No.: US 2006/0148208 A1
(43) Pub. Date: Jul. 6, 2006

(54) Method for producing a silicon-on-insulator structure

(76) Inventors: Vladimir Pavlovich Popov, Novosibirsk (RU); Ida Evgenievna Tyschenko, Novosibirsk (RU)

Correspondence Address: LADAS & PARRY, 26 WEST 61ST STREET, NEW YORK, NY, 10023, US

(21) Appl. No.: 10/542,123

(22) PCT Filed: Jan. 14, 2004
(86) PCT No.: PCT/RU04/00006

§ 371 Date: Dec. 9, 2005

(30) Foreign Application Priority Data
Jan. 14, 2003 (RU) 2003100747

(51) Int. Cl. H01L 21/30; H01L 21/425

(52) U.S. Cl. 438/458; 438/516

(57) ABSTRACT

The inventive method for producing a silicon-on insulator structure consists in implanting hydrogen is a silicon plate (1), chemically treating said silicon plate (1) and a substrate (3), in connecting and grafting the silicon plate (1) and the substrate (3) and in layering along the implanted layer (2) of the plate (1). The drying, removal of physically adsorbed substances from the surface of the plate (1) and the substrate (3), connection of the plate (1) and the substrate (3), the grafting and layering thereof along the implanted layer (2) of the plate is carried out after the chemical treatment in one stage, in a low vacuum, at a temperature when hydrogen introduced by implantation remains in a bound state.

### FIELD OF THE INVENTION

The invention belongs to semiconductor technology and more exactly deals with the method for producing a silicon-on-insulator (SOI) structure.

### DESCRIPTION OF THE PRIOR ART

The method for producing a silicon-on-insulator structure is known (U.S. Pat. No. 5,374,564), contained hydrogen implantation in a first wafer, bonding the first wafer with the second wafer and slicing the first wafer. The implantation is realized by ion bombardment of the first wafer with the ions that create a layer, which contains the gas filled micropores in the volume of the first wafers at the depth near the penetration distance of the ions. This layer divides the wafer into the bottom part, that contains the substrate, and the upper part, that contains the thin film. At that hydrogen ions or inert gas ions are used, and the temperature of first wafer is maintained below the temperature, at which the gas created by implanted ions is diffused out of volume of implanted semiconductor. An exfoliation of the bonded wafers are carried out at high temperature which is higher than the temperature of ion implantation and which is enough for a recovery of material structure in the first wafer and for an increasing a gas pressure in the micropores in implanted layers that separate the thin film and the substrate. At this time the first and the second wafers are kept at closed contact. The implantation is carried out through one or more layers on the first wafer, which are consist of different materials with total thickness lower than penetration depth of ions. The temperature of the first wafer is kept during the implantation between 20 and 450° C., and the exfoliation is carried out at the temperature higher than 500° C. The implantation is carried out through dioxide layer, which is used as a buried oxide, and the initial silicon wafer is used as the second wafer.

The described above method has a lot of disadvantages that lead to decreasing a quality of produced silicon-on-insulator structures.

Firstly, this is the low quality of buried oxide in SOI structures, which are produced by described method. Namely, the H⁺ ion implantation is carried out through the silicon dioxide that is used afterward as the buried oxide (BOX). Generated during the implantation defects as well as the rest of implanted hydrogen deteriorate isolation properties of SiO₂ BOX layer. In one's turn an using this SiO₂ layer as insulating dielectric is determined by its breakdown voltage, leakage current wich are limited at this case by the quantities of generated defects and hydrogen content. They can be diminish completely only after very high temperature annealing e.g. 1100° C. during more than 2 hours.

Secondly, Using as a BOX layer in the above mentioned method a thermal oxide grown just on the first wafer leads to that the boundary between the separated silicon layer and the BOX layer is the transient region Si/thick thermal SiO₂. This transient layer may be as thick as few nanometers that limits an using of such SOI structures for extremely thin devices with low dimension channels (nano field effect transistors, single electron transistors and quantum devices), where the quality of grain boundary should be extremely high.

Thirdly, the need of using relatively high energy H⁺ ion implantation due to pass the oxide layer and exfoliate thin silicon layer beneath leads to high straggling in projected range of H⁺ ions, and properly to the increase in dose needed for exfoliation and defects and hydrogen content in BOX, and to increase in roughness of exfoliated film surface.

Fourthly, it leads to an inhomogeneity in transferring of exfoliated film on the area of first wafer due to starting of exfoliation at few places at the high enough temperature of exfoliation ˜500° and higher.

Fifthly, hydrogen and other gases flatulence in the pores at the bonded interface renders impossible the whole film transfer due to initial adsorbed substances at the surfaces of the bonded wafers with following flaking of transferred film during high temperature treatment in the case of mentioned above method (U.S. Pat. No. 5,374,564), when only one Si layer is transferred on the other substrates.

More related method for the set of signs and the purpose is a method for producing a silicon-on-insulator (SOI) structure (Invention of RF no. 2164719, IPC: H 01 L 21/324), contained an implantation of hydrogen ions in the first wafer, the thermal oxide growth on the second wafer, the chemical treatment of the first and second wafers, their direct bonding, drying, and exfoliation in the first wafer with following removing of damaged surface layer on the SOI structure. The grown on the second wafer thermal oxide has a thickness of 0.2÷0.5 μm. Hydrogen implantation is carried out through initially grown thin oxide SiO₂ layer (20÷50 nm), that is deleted by etching after implantation with dose of H₂⁺ ions (2.5÷5)×10¹⁶ cm⁻². Direct bonding of the wafers is carried out in the air at 150÷250° C. during 1-2 hours. Exfoliation of the first wafer is provided with annealing at 350÷450° C. during 2-0.5 hours, respectively. High temperature annealing at 1100° C. during 0.5÷1 hour is used for complete defect removing. Subsurface damaged layer is removed by touch polishing with previous oxidation and etching.

This known technical solution also has the disadvantages, that diminish the quality of silicon-on-insulator wafers. They include:

Firstly, storage of the pores at the bonded interface due to initial hydrogen accumulation at the pores, created by residual impurities, physically adsorbed at the surfaces of the bonded wafers with following flaking of transferred film due to hydrogen release during high temperature treatment.

Secondly, using of thermal treatment at 350° C. that coincide with the beginning of hydrogen detrapping from bonded states and hydrogen filled pore formation that placed inside of implanted layer and cause the inhomogeneous silicon layer transfer along the wafer surface with rough surface of final SOI surface.

### SUMMARY OF THE INVENTION

The technical result of the invention is an improvement of quality of SOI structure.

The technical result is reached thereby, that hydrogen implantation is carried out in the first wafer, the thermal oxide is grown on the second wafer, the first and the second wafers are treated chemically and directly bonded, spliced and exfoliated at the implanted layer in the first wafer, at that drying after chemical treatment, removing of physically adsorbed substances from the wafer surfaces, joining the wafers, their splicing and exfoliating of the first wafer are carried out in one stage in the low vacuum at the temperature, at which the implanted hydrogen atoms are remained in the connected state.

Preferably, in the method the hydrogen implantation is carried out in the first wafer through preliminary grown thin (5÷50 nm) thermal SiO2 layer, which is removed after implantation.

Preferably, in the method H₂⁺ or H⁺ ions are used with the doses (1,5÷15)×10¹⁶ cm⁻² and energies of 20÷200 keV.

Preferably, in the method the thermally grown oxide thickness on the second wafer is equal to 0.01÷3 μm.

Preferably, in the method high temperature annealing is carried out at 1100° C. during 0.5÷1 hour.

Preferably, in the method a subsurface damaged layer in the silicon-on-insulator structure, obtained in the result of exfoliating at the hydrogen implanted layer inside the silicon wafer, is removed by oxidation and etching and by touch polishing.

Preferably, in the method silicon wafer is used as a substrate, at which the thermal oxide is grew before the thermal treatment.

According to another preferable variant of the executing the method a glass wafer is used as a substrate with the thickness near 500 μm.

According to one's more preferable variant of the executing the method a quartz wafer is used as a substrate with the thickness near 500 μm.

According to the most preferable variant of the executing the method drying, removing of the of physically adsorbed substances from the first wafer and substrate surfaces, joining the wafers, their splicing and exfoliating of the first wafer are carried out in the low vacuum (10¹÷10⁴ Pa) at the temperature interval from 80° to 350° C. with duration from 0.1 to 100 hours.

### BRIEF DESCRIPTION OF THE DRAWINGS

The substance of the invention is explained by the following description and enclosed figures.

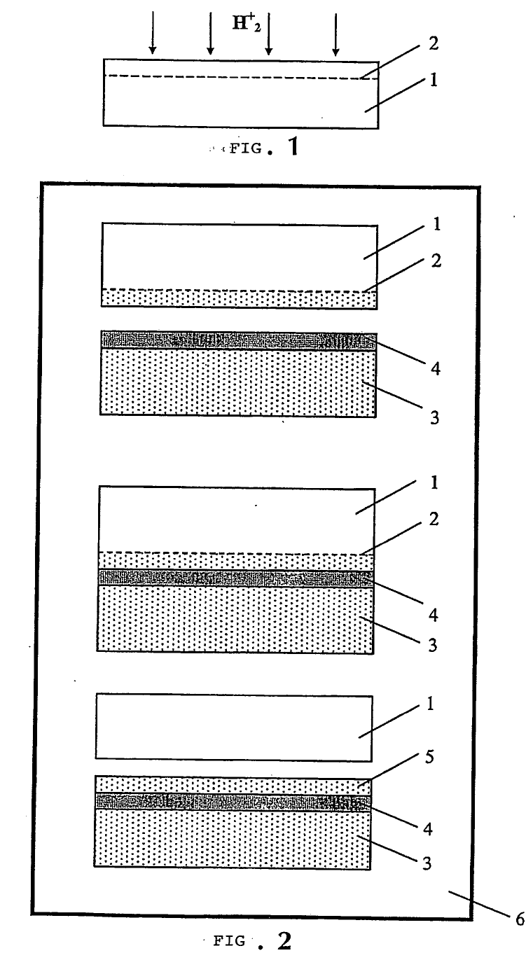

The stage of hydrogen implantation for producing SOI structure by the claimed method is presented on the FIG. 1.

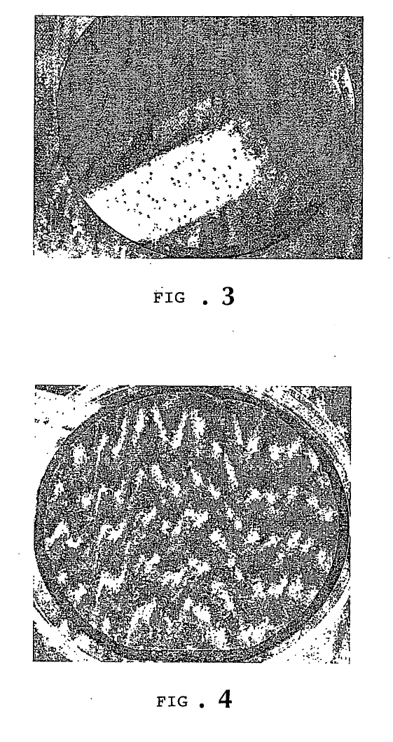

The stage of drying, removing of the of physically adsorbed substances from the first wafer and substrate surfaces, joining the wafers, their splicing and exfoliating of the first wafer for obtaining thin silicon film in the low vacuum chamber are presented on the FIG. 2.

The photo of the surface for SOI structure, which was produced at the atmosphere pressure is presented on the FIG. 3.

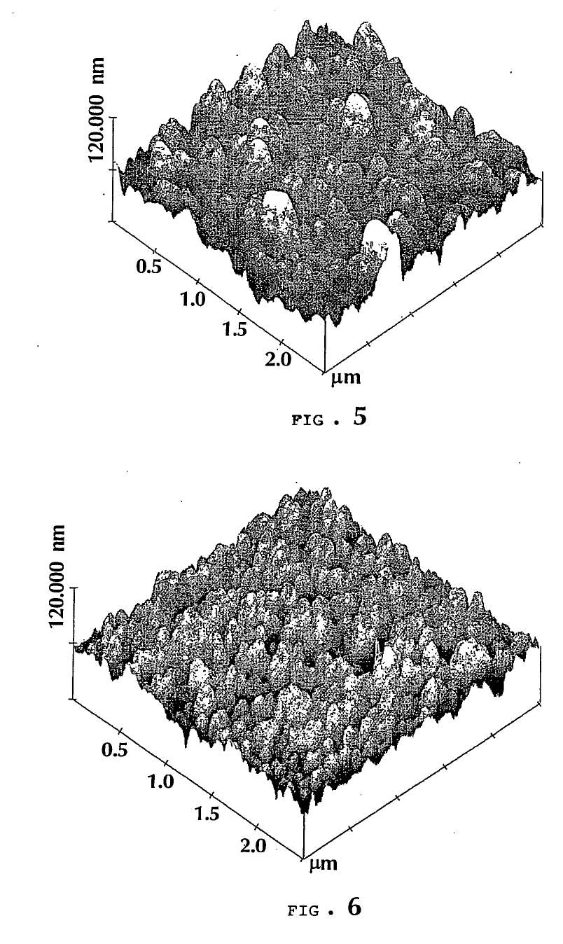

The photo of the surface for SOI structure, which was produced at low pressure conditions is presented on the FIG. 4.

The atomic force microscopy (AFM) image of the surface roughness (root mean square roughness ˜11.3 nm) for SOI structure, which was produced by H⁺ ion implantation with energy of 100 keV is presented on the FIG. 5.

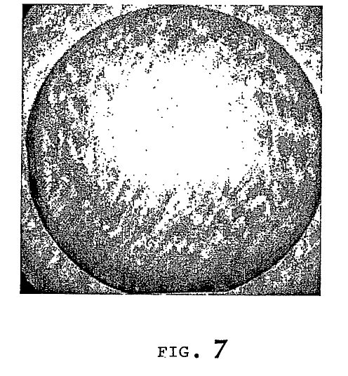

The atomic force microscopy (AFM) image of the surface roughness (root mean square roughness ˜6.7 nm) for SOI structure, which was produced by H⁺ ion implantation with energy of ˜20 keV is presented on the FIG. 6.

The photo of the surface for SOI structure, which was produced by the claimed method is presented on the FIG. 7. There aren't microblisters and micropipes with dimensions larger than 0.25 μm on the surface of SOI wafer.

### DETAILED DESCRIPTION OF THE INVENTION

Physical basis of the claimed method for producing of SOI structure with low vacuum and low temperature splicing of silicon wafers with transferring at that time the thin silicon film (a constituent element of SOI structure) is a difference for the surface energies of the pair of hydrophilic surfaces Si/SiO₂ and of the pair of hydrophobic surfaces Si/Si in the different temperature intervals. Particularly, the quantity of the surface energy of the pair of hydrophilic surfaces Si/SiO₂ is larger than the quantity of the surface energy of the pair of hydrophobic surfaces Si/Si at the temperatures 20÷500° C. This excess can be as high as one order of magnitude at the temperature interval 150÷300° C. It should be mentioned that these temperatures are lower than the temperatures that were used for splicing and transferring of the thin film of silicon and silicon dioxide layers by the known method for producing SOI wafers ((U.S. Pat. No. 5,374,564, IPC: 5 H01L 21/265), which are equal to ˜500° C. and are choused reasoning from the conditions for hydrogen release from the connected states and its transition into micropores for increase in pressure inside. These conditions are necessary for the exfoliation of first wafer along the implanted layer. In respect to the claimed method producing of SOI structure can be considerate as a process of joining the hydrophilic surfaces (splicing for silicon wafers) and the break up of the hydrophobic bonds at the inner surfaces (hydrogen induced thin film transfer) at the temperatures in the indicated interval. Two main tasks should be solved for the implementation of the claimed method. Firstly, high performance outer hydrophilic surfaces should be produced. Secondly, inner hydrophobic surfaces inside the silicon wafer should be created.

Parameters that determine the quantity of the surface energy in each case are served the temperature and the structural quality of the surfaces. That means the need of extremely high cleanness for the splicing surfaces without physically adsorbed impurities on the initial surfaces for the 100% bonding of these two surfaces. Standard RCA cleaning procedure (Semiconductor Wafer Bonding. Science and Technology, Q.-Y. Tong, U. Gosele, John Wiley & Sons, Inc., New York, N.Y., 10158-0012, p. 52) were used for reaching the needed cleanness that was consisted of ammonia-peroxide solution, etching of natural oxide by diluted hydrofluoric acid and final treatment in the peroxide-acid solution. The rinsing in ultra pure deionized water was used after each treatment. Wafer bonding was carried out between the hydrophilic surfaces obtained by the treatment at peroxide-acid solution with different ratios (RCA-1, RCA-2), which provides a contact angles for silicon and silicon dioxide lying from 0 to 10° (Semiconductor Wafer Bonding. Science and Technology, Q.-Y. Tong, U. Gosele, John Wiley & Sons, Inc., New York, N.Y., 10158-0012, p. 62). The wafers are placed in a centrifuge inside the low vacuum chamber to drying and removing of physically adsorbed substances from the first wafer and substrate surfaces and heated up to 80÷350° C. and then the wafers were bonded together in pairs.

Inner hydrophobic surfaces in the neighboring atomic planes parallel to the wafer surface can be formed in hydrogen implanted silicon layer. Their formation takes place by the constitution of Si—H—H—Si bonds in this layer due to trapping of hydrogen atoms on the stretched and weakened Si—Si bonds hat is perpendicular to the surface. In order to provide a formation of two hydrophobic (100) planes with 100% covering by Si—H—H—Si bonds the dose of H⁺ ions with energies 20÷200 keV should be at least 3×10¹⁷ cm⁻² and higher. But even at the dose ˜1,5×10¹⁶ cm⁻² for energy ˜20 keV the microcracks start to constitute inside the implanted layer. Their presence weakens Si—Si bonds in implanted layer with the surface energies closed to hydrophobically bonded silicon surfaces. Practically, no need for 100% covering by Si—H—H—Si bonds in inner (100) surfaces. Starting from this consideration the hydrogen doses choused in claimed invention were from 1,5×10¹⁶ to 1,5×10¹⁷ crmf⁻² for ion energies 20÷200 keV respectively.

Based on presented physical representations an attainment of the technical result was obtained by realization of the next stages, where the major stages are two that are presented on the FIGS. 1 and 2 at the next conditions.
1. Hydrogen ion implantation is carried out at the first major stage (FIG. 1) in the wafer 1 with ion energies 20÷200 keV through thin SiO₂ layer 5÷50 nm, which prevents the surface contamination and following it is removed. Hydrogen implanted layer position is signed by 2 in FIG. 1. Hydrogen dose, needed for exfoliation of thin silicon film at the following thermal treatments is 1,5×10¹⁶÷1,5×10¹⁷ cm⁻² for ion energies 20÷200 keV, respectively.
2. Thermally oxidized silicon wafer is used as a substrate 3 (FIG. 1). The oxide layer 4, which will be the buried oxide after bonding of the silicon wafer 1 and substrate 3 is grown thermally on the wafer 3, which will be the substrate, and this oxide is not irradiated by ions that keeps its high quality in SOI structure.
3. Chemical treatment of the wafer 1 and the substrate 3 is carried out including water stream douche or ultrasonic water stream, hydrophilisation of the wafer 1 and the substrate 3 with following water stream douche or ultrasonic deionized water stream. Cleaning and hydrophilisation of surfaces of implanted wafer 1 and unimplanted substrate 3 is carried out using treatment in the peroxide-acid and ammonia-peroxide solutions with different ratios NH₄OH:H₂O:H₂O=1:1:5÷1:2:7 and HCl:H₂O₂:H₂O=1:1:6÷1:2:8 (RCA-1 and RCA-2, respectively).
4. Drying, removing of the of physically adsorbed substances from the surfaces of wafer 1 and substrate 3, joining the wafer 1 and substrate 3, their splicing and exfoliating along the implanted layer 2 in the wafer 1 at the temperatures 80÷350° C. with duration from 0.1 to 100 hours in the same low vacuum chamber (10^{1÷10}⁴ Pa) are carried out at the second major stage (FIG. 2).
5. Concluding high temperature annealing is carried out at 1100°±50° C. during 0.5÷1 hour, which is needed in some cases for increasing the bonding energies between the silicon wafer 1 and the substrate 3 to the value of breaking energy for the bulk silicon, as well as for removing of the residual radiation defects and hydrogen atoms from the exfoliated silicon layer
6. Touch polishing or oxidation with following etching is carried out for removing of upper damaged layer 5 of exfoliated silicon film.

Thus, the main difference of the claimed method for producing of SOI structure by the hydrogen-induced transfer is concluded thereby, that drying, removing of the of physically adsorbed substances from the surfaces of the wafers, joining the wafer and substrate, their splicing and exfoliating along the implanted layer in the wafer at the temperatures 80÷350° C. with duration from 0.1 to 100 hours are carried out in the one stage in the same low vacuum chamber (10¹÷10⁴ Pa) (FIG. 2). SOI structures produced at the low vacuum conditions have a higher quality, which is manifested in the absence of microblisters and micropipes that is demonstrated by the FIG. 4 in comparison with the SOI structure obtained at the atmosphere conditions that is presented on the FIG. 3. An increase in the bonding energy between the wafer and substrate allows to decrease the implantation energy and the thickness of transferred layer, that also provides a decrease in the roughness of SOI wafer surface (FIG. 6) as well as the total radiation-thermal impact on the structure used for SOI producing in comparison with the roughness of SOI wafer surface produced by hydrogen ions with more higher energy (FIG. 5).

The examples of specific realizations are presented below for more exact understanding of the substance for claimed invention.

### EXAMPLE 1

1. H₂⁺ ion implantation is carried out in silicon wafer with ion energy 140 keV and dose 2,5×10¹⁶ crm² through thin 50 nm SiO₂ layer, which prevents the surface contamination and following it is removed.
2. Silicon wafer with grown thermal oxide SiO₂ (280 nm) is used as a substrate.
3. Chemical treatment of implanted silicon wafer and substrate is carried out including cleaning with deionized water stream douche or ultrasonic deionized water stream and hydrophilisation of surfaces of implanted wafer and unimplanted substrate, using treatment in the peroxide-acid and ammonia-peroxide solutions with following cleaning by water stream douche or ultrasonic deionized water stream.
4. H₂⁺ implanted silicon wafer and silicon wafer with grown thermal oxide are placed in low vacuum chamber with pressure 10² Pa and heated to the temperature 300° C., dried and cleaned from the physically adsorbed substances during 0.1 hour and then joined together, spliced and exfoliated along the implanted layer at the same conditions during 40 hours. In the result spontaneous exfoliation occurs and the final SOI structure appears with 0.6 μm Si/0.28 μm SiO₂/Si substrate. The photo of the surface for produced SOI structure is presented on the FIG. 7, which demonstrates the absence of microblisters and micropipes with dimensions larger than 0.25 μm on the surface of SOI wafer.
5. Touch chemical-mechanical polishing (CMP) is carried out for removing of upper damaged layer on the surface of exfoliated silicon film in SOI structure.

### EXAMPLE 2

1. H₂⁺ ion implantation is carried out in silicon wafer with ion energy 40 keV and dose 1,5×10¹⁶ cm⁻² through thin 5 nm SiO₂ layer, which prevents the surface contamination and following it is removed.
2. Silicon wafer with grown thermal oxide SiO₂ (280 nm) is used as a substrate.
3. Chemical treatment of implanted silicon wafer and substrate is carried out including cleaning with deionized water stream douche or ultrasonic deionized water stream and hydrophilisation of surfaces of implanted wafer and unimplanted substrate, using treatment in the RCA and ammonia-peroxide solutions with following cleaning by water stream douche or ultrasonic deionized water stream.
4. H₂⁺ ion implanted silicon wafer and silicon wafer with grown thermal oxide are placed in low vacuum chamber with pressure 10¹ Pa and heated to the temperature 200° C., dried and cleaned from the physically adsorbed substances during 0.15 hour, then joined together and heated to 300° C., spliced and exfoliated along the implanted layer at the same conditions during 40 hours. In the result spontaneous exfoliation occurs and the final SOI structure appears with 0.2 μm Si/0.28 μm SiO₂/Si substrate. The investigation of the surface for produced SOI structure demonstrates the absence of microblisters and micropipes with dimensions larger than 0.25 μm on the surface of SOI wafer.
5. Thermal oxidation and chemical etching in diluted hydrofluoric acid is carried out for removing of upper damaged layer on the surface of exfoliated silicon film in SOI structure.

### EXAMPLE 3

1. H₂⁺ ion implantation is carried out in silicon wafer with ion energy 140 keV and dose 5×10¹⁶ cm⁻² through thin 50 nm SiO₂ layer, which prevents the surface contamination and following it is removed.
2. Silicon wafer with grown thermal oxide SiO₂ with the thickness 280 nm is used as a substrate.
3. Chemical treatment of implanted silicon wafer and substrate is carried out including cleaning with deionized water stream douche or ultrasonic deionized water stream and hydrophilisation of surfaces of implanted wafer and unimplanted substrate, using treatment in the RCA and ammonia-peroxide solutions with following cleaning by water stream douche or ultrasonic deionized water stream.
4. H₂⁺ ion implanted silicon wafer and silicon wafer with grown thermal oxide are placed in low vacuum chamber with pressure 10² Pa and heated to the temperature 150° C., dried and cleaned from the physically adsorbed substances during 0.2 hour, then joined together and heated to 300° C., spliced and exfoliated along the implanted layer at the same conditions during 10 hours, then the joined wafer and substrate are removed from low vacuum chamber and are exfoliated mechanically in the air, and the final SOI structure appears with 0.6 μm Si/0.28 μm SiO₂/Si substrate. The investigation of the surface for produced SOI structure demonstrates the absence of microblisters and micropipes with dimensions larger than 0.25 μm on the surface of SOI wafer.
5. Thermal treatment of SOI structure at the temperature 1100° C. during 1 hour is carried out for removing of the rest defects and hydrogen atoms.
6. Touch chemical-mechanical polishing (CMP) is carried out for removing of upper rough layer on the surface of exfoliated silicon film in SOI structure.

### EXAMPLE 4

1. H⁺ ion implantation is carried out in silicon wafer with ion energy 20 keV and dose 4×10¹⁶ cm⁻² through thin 5 nm SiO₂ layer, which prevents the surface contamination and following it is removed.
2. Silicon wafer with grown thermal oxide SiO₂ with the thickness 10 nm is used as a substrate.
3. Chemical treatment of implanted silicon wafer and substrate is carried out including cleaning with deionized water stream douche or ultrasonic deionized water stream and hydrophilisation of surfaces of implanted wafer and unimplanted substrate, using treatment in the RCA and ammonia-peroxide solutions with following cleaning by water stream douche or ultrasonic deionized water stream.
4. H⁺ ion implanted silicon wafer and silicon wafer with grown thermal oxide are placed in low vacuum chamber with pressure 10² Pa and heated to the temperature 300° C., dried and cleaned from the physically adsorbed substances during 0.1 hour, then joined together and heated to 300° C., spliced and exfoliated along the implanted layer at the same conditions during 40 hours. In the result spontaneous exfoliation occurs and the final SOI structure appears with 0.2 μm Si/0.28 μm SiO₂/Si substrate. The investigation of the surface for produced SOI structure demonstrates the absence of microblisters and micropipes with dimensions larger than 0.25 μm on the surface of SOI wafer.
5. Thermal oxidation and chemical etching in diluted hydrofluoric acid is carried out for removing of upper damaged layer on the surface of exfoliated silicon film in SOI structure.

### EXAMPLE 5

1. H⁺ ion implantation is carried out in silicon wafer with ion energy 200 keV and dose 1.5×10¹⁷ cm⁻² through thin 50 nm SiO₂ layer, which prevents the surface contamination and following it is removed.
2. Silicon wafer with grown thermal oxide SiO₂ with the thickness 410 nm is used as a substrate.
3. Chemical treatment of implanted silicon wafer and substrate is carried out including cleaning with deionized water stream douche or ultrasonic deionized water stream and hydrophilisation of surfaces of implanted wafer and unimplanted substrate, using treatment in the RCA and ammonia-peroxide solutions with following cleaning by water stream douche or ultrasonic deionized water stream.
4. H⁺ ion implanted silicon wafer and silicon wafer with grown thermal oxide are placed in low vacuum chamber with pressure 10⁴ Pa and heated to the temperature 350° C., dried and cleaned from the physically adsorbed substances during 0.1 hour, then joined together, spliced and exfoliated along the implanted layer at the same conditions during 5 hours. In the result spontaneous exfoliation occurs and the final SOI structure appears with 1.8 μm Si/0.41 μm SiO₂/Si substrate. The investigation of the surface for produced SOI structure demonstrates the absence of microblisters and micropipes with dimensions larger than 0.25 μm on the surface of SOI wafer.
5. Thermal oxidation and chemical etching in diluted hydrofluoric acid is carried out for removing of upper damaged layer on the surface of exfoliated silicon film in SOI structure.

### EXAMPLE 6

1. H₂⁺ ion implantation is carried out in silicon wafer with ion energy 140 keV and dose 6×10¹⁶ cm⁻² through thin 50 nm SiO₂ layer, which prevents the surface contamination and following it is removed.
2. Silicon wafer with grown thermal oxide SiO₂ with the thickness 280 nm is used as a substrate.
3. Chemical treatment of implanted silicon wafer and substrate is carried out including cleaning with deionized water stream douche or ultrasonic deionized water stream and hydrophilisation of surfaces of implanted wafer and unimplanted substrate, using treatment in the RCA and ammonia-peroxide solutions with following cleaning by water stream douche or ultrasonic deionized water stream.
4. H₂⁺ ion implanted silicon wafer and silicon wafer with grown thermal oxide are placed in low vacuum chamber with pressure 10² Pa and heated to the temperature 80° C., dried and cleaned from the physically adsorbed substances during 1 hour, then joined together and heated to 300° C., spliced and exfoliated along the implanted layer at the same conditions during 25 hours. In the result spontaneous exfoliation occurs, and the final SOI structure appears with 0.6 μm Si/0.28 μm SiO₂/Si substrate. The investigation of the surface for produced SOI structure demonstrates the absence of microblisters and micropipes with dimensions larger than 0.25 μm on the surface of SOI wafer.
5. Thermal treatment of SOI structure at the temperature 1100° C. during 1 hour is carried out for removing of the rest defects and hydrogen atoms.
6. Touch chemical-mechanical polishing (CMP) is carried out for removing of upper rough layer on the surface of exfoliated silicon film in SOI structure.

### EXAMPLE 7

1. H⁺ ion implantation is carried out in silicon wafer with ion energy 20 keV and dose 4×10¹⁶ cm⁻² through thin 5 nm SiO₂ layer, which prevents the surface contamination and following it is removed.
2. Silicon wafer with grown thermal oxide SiO₂ with the thickness 3.0 μm is used as a substrate.
3. Chemical treatment of implanted silicon wafer and substrate is carried out including cleaning with deionized water stream douche or ultrasonic deionized water stream and hydrophilisation of surfaces of implanted wafer and unimplanted substrate, using treatment in the RCA and ammonia-peroxide solutions with following cleaning by water stream douche or ultrasonic deionized water stream.
4. H⁺ ion implanted silicon wafer and silicon wafer with grown thermal oxide are placed in low vacuum chamber with pressure 10² Pa and heated to the temperature 350° C., dried and cleaned from the physically adsorbed substances during 0.1 hour, then joined together, spliced and exfoliated along the implanted layer at the same conditions during 10 hours. In the result spontaneous exfoliation occurs, and the final SOI structure appears with 0.2 μm Si/3.0 μm SiO₂/Si substrate. The investigation of the surface for produced SOI structure demonstrates the absence of microblisters and micropipes with dimensions larger than 0.25 μm on the surface of SOI wafer.
5. Thermal treatment of SOI structure at the temperature 900° C. during 1 hour is carried out for removing of the rest defects and hydrogen atoms.
6. Touch chemical-mechanical polishing (CMP) is carried out for removing of upper rough layer on the surface of exfoliated silicon film in SOI structure.

### EXAMPLE 8

1. H₂⁺ ion implantation is carried out in silicon wafer with ion energy 140 keV and dose 3.5×10¹⁶ cm⁻² through thin 50 nm SiO₂ layer, which prevents the surface contamination and following it is removed.
2. Glass (type LK-5 or Pyrex) wafer with the thickness 500 μm after CMP is used as a substrate.
3. Chemical treatment of implanted silicon wafer and substrate is carried out including cleaning with deionized water stream douche or ultrasonic deionized water stream and hydrophilisation of surfaces of implanted wafer and unimplanted substrate, using treatment in the RCA and ammonia-peroxide solutions with following cleaning by water stream douche or ultrasonic deionized water stream.
4. H₂⁺ ion implanted silicon wafer and silicon wafer with grown thermal oxide are placed in low vacuum chamber with pressure 10² Pa and heated to the temperature 300° C., dried and cleaned from the physically adsorbed substances during 0.1 hour, then joined together, spliced and exfoliated along the implanted layer at the same conditions during 30 hours. In the result spontaneous exfoliation occurs, and the final SOI structure appears with 0.6 μm Si/500 μm SiO₂ glass substrate. The investigation of the surface for produced SOI structure demonstrates the absence of microblisters and micropipes with dimensions larger than 0.25 μm on the surface of silicon-on-glass (SOG) wafer.
5. Thermal treatment of SOG structure at the temperature 650° C. during 10 hours is carried out for removing of the rest defects and hydrogen atoms.
6. Touch chemical-mechanical polishing (CMP) is carried out for removing of upper rough layer on the surface of exfoliated silicon film in SOG structure.

### EXAMPLE 9

1. H₂⁺ ion implantation is carried out in silicon wafer with ion energy 140 keV and dose 3.5×10¹⁶ cm⁻² through thin 50 nm SiO₂ layer, which prevents the surface contamination and following it is removed.
2. Glass (type LK-5 or Pyrex) wafer with the thickness 500 μm after CMP is used as a substrate.
3. Chemical treatment of implanted silicon wafer and substrate is carried out including cleaning with deionized water stream douche or ultrasonic deionized water stream and hydrophilisation of surfaces of implanted wafer and unimplanted substrate, using treatment in the RCA and ammonia-peroxide solutions with following cleaning by water stream douche or ultrasonic deionized water stream.
4. H₂⁺ ion implanted silicon wafer and silicon wafer with grown thermal oxide are placed in low vacuum chamber with pressure 10³ Pa and heated to the temperature 350° C., dried and cleaned from the physically adsorbed substances during 0.1 hour, then joined together with applying the electric field them (negative electrode is placed at the glass), spliced and exfoliated along the implanted layer at the same conditions during 30 hours. In the result spontaneous exfoliation occurs, and the final structure appears with 0.6 μm Si/500 μm SiO₂ glass substrate. The investigation of the surface for produced structure demonstrates the absence of microblisters and micropipes with dimensions larger than 0.25 μm on the surface of silicon-on-glass (SOG) wafer.
5. Thermal treatment of SOG structure at the temperature 650° C. during 10 hours is carried out for removing of the rest defects and hydrogen atoms.
6. Touch chemical-mechanical polishing (CMP) is carried out for removing of upper rough layer on the surface of exfoliated silicon film in SOG structure.

### EXAMPLE 10

1. H₂⁺ ion implantation is carried out in silicon wafer with ion energy 40 keV and dose 2.5×10¹⁶ cm⁻² through thin 5 nm SiO₂ layer, which prevents the surface contamination and following it is removed.
2. Quartz wafer with the thickness 500 μm after CMP is used as a substrate.
3. Chemical treatment of implanted silicon wafer and substrate is carried out including cleaning with deionized water stream douche or ultrasonic deionized water stream and hydrophilisation of surfaces of implanted wafer and unimplanted substrate, using treatment in the RCA and ammonia-peroxide solutions with following cleaning by water stream douche or ultrasonic deionized water stream.
4. H₂⁺ ion implanted silicon wafer and silicon wafer with grown thermal oxide are placed in low vacuum chamber with pressure 10² Pa and heated to the temperature 300° C., dried and cleaned from the physically adsorbed substances during 0.1 hour, then joined together, spliced at the same conditions during 30 hours and cooled to room temperature. During cooling spontaneous exfoliation occurs, and the final structure appears with 0.6 μm Si/500 μm quartz substrate. The investigation of the surface for produced structure demonstrates the absence of microblisters and micropipes with dimensions larger than 0.25 μm on the surface of silicon-on-quartz (SOQ) wafer.
5. Thermal treatment of SOQ structure at the temperature 650° C. during 10 hours is carried out for removing of the rest defects and hydrogen atoms.
6. Touch chemical-mechanical polishing (CMP) is carried out for removing of upper rough layer on the surface of exfoliated silicon film in SOQ structure.

Thus as it is seen from the examples the claimed method for producing silicon-on-insulator structures using drying, removing of the of physically adsorbed substances from the surfaces of the wafers, joining the wafer and substrate, their splicing and exfoliating (hydrogen induced transferring along the implanted layer in the wafer in the low vacuum conditions at the moderate temperatures allows in comparison with known technical solution:
1. to decrease of needed ion energy and respectively decrease the thickness of transferred (exfoliated) layer;
2. to decrease of needed hydrogen ion dose and respectively decrease of irradiation time;
3. to decrease of roughness of SOI structure surface as well as the total radiation-thermal impact on the structures used for SOI producing;
4. to decrease of defect concentration at the grain boundary Si/SiO₂;
5. to get practically full absence of microblisters on the SOI surface and micropipes in the silicon film;
6. to improve the quality and yield of suitable SOI wafers,
7. to reduce the cost of SOI structures produced by the claimed method, based on hydrogen induced trahsfer, due to absence of slicing (exfoliating) procedure at the temperatures 400÷600° C. needed in the known method for hydrogen gas filled micropore formation and thermally induced splitting.

These advantages are the consequence of desorption of water and other physically adsorbed substances from the surfaces of joined wafers at moderate heating in low vacuum conditions and also the consequence of few order of magnitude decreasing the gas quantity trapped at the micropores between the joined wafers that leads during further thermal treatment to micorbubles (microblisters) and microcraters (micropipes) in cut off silicon layer of SOI structure.

### INDUSTRIAL APPLICABILITY

Claimed invention can be used in the field of producing the modern materials for microelectronics, and particularly, silicon-on-insulator structures (SOI) fro producing of modern ultra large scale integrated circuits and other microelectrinc devices.

What is claimed is:

1. A method for producing a silicon-on-insulator structure including hydrogen implantation in silicon wafer, chemical treatment of silicon wafer and substrate, joining of silicon wafer and substrate, splicing and splitting of wafer along the implanted layer characterized in that a drying, removing of the of physically adsorbed substances from the surfaces of the wafers after chemical treatment is carried out in the low vacuum conditions at the moderate temperatures at which the implanted hydrogen is staying in the in the bound state and joining the wafer and substrate, their splicing and exfoliating hydrogen induced transferring along the implanted layer in the wafer in the same low vacuum conditions at the same or slightly higher moderate temperatures at which the implanted hydrogen is staying mostly in the bound state.

2. The method according to claim 1, characterized in that the hydrogen implantation is carried out through thermally grown oxide SiO₂ with the thickness 5 to 50 nm and following it is removed after implantation.

3. The method according to claim 1, characterized in that the hydrogen implantation is carried out with H⁺₂ or H⁺ ions with doses (1.5 to 15)×10¹⁶ cm⁻² and energies 20 to 200 keV, respectively.

4. The method according to claim 1, characterized in that a thermal annealing is carried out at 1100° C. during 0.5 to 1 hour after splitting.

5. The method according to claim 1, characterized in that a touch chemical-mechanical polishing (CMP) or thermal oxidation with following chemical etching in diluted hydrofluoric acid are carried out for removing of upper rough layer on the surface of exfoliated silicon film.

6. The method according to claim 1, characterized in that the thickness of thermally grown oxide SiO₂ with on the substrate is equal to 0.01 to 3 μm.

7. The method according to claim 1, characterized in that the substrate is a glass wafer with the thickness about 500 μm.

8. The method according to claim 1, characterized in that the substrate is a quartz wafer with thickness about 500 μm.

9. The method according to claim 1, characterized in that the drying, removing of the of physically adsorbed substances from the surfaces of the wafer and substrate, joining the wafer and substrate, their splicing and exfoliating along the implanted layer in the wafer at the temperatures 80 to 350° C. with duration from 0.1 to 100 hours are carried out in the low vacuum conditions (10¹ to 10⁴ Pa).
